(19) United States
(12) Patent Application Publication
(10) Pub. No.: US 2022/0178974 A1
(43) Pub. Date: Jun. 9, 2022

(54) VOLTAGE INDICATOR

(71) Applicant: Grace Technologies, Inc., Davenport, IA (US)

(72) Inventors: Richard Haberkern, Burbank, CA (US); Bryan Van Itallie, Davenport, IA (US); José Miguel Pedraza Cruz, Chia - Cundinamarca (CO); Edgaras Korsakas, Kuktiskës (LT)

(73) Assignee: Grace Technologies, Inc., Davenport, IA (US)

(21) Appl. No.: 17/116,433

(22) Filed: Dec. 9, 2020

(51) Int. Cl. G01R 19/155; G01R 19/165; H05B 45/305; G08B 5/38

(52) U.S. Cl. CPC G01R 19/155; G08B 5/38; H05B 45/305; G01R 19/16538

(57) ABSTRACT

An electrical safety monitoring device includes a first set of digital switches and a second set of digital switches for each of a plurality of line inputs, a first set of visual indicators, wherein each of the first set of visual indicators is electrically connected to one of the first set of digital switches and a second set of visual indicators, wherein each of the second set of visual indicators is electrically connected to one of the second set of digital switches. There is a first voltage-controlled oscillator operatively connected to the first set of digital switches for controlling a flash rate of the first set of visual indicators when the positive voltage is present and a second voltage-controlled oscillator operatively connected to the second set of digital switches for controlling a flash rate of the second plurality of visual indicators when a magnitude of the negative voltage is present.

### FIELD OF THE INVENTION

The present invention relates to voltage monitoring. More particularly, but not exclusively, the present invention relates to a voltage indicator suitable for use in industrial environments and other applications where power monitoring is desired.

### BACKGROUND

Various voltage indicator devices and associated circuitry exist. Generally, the purpose of a voltage indicator is to visually communicate the presence or absence of voltage to trained individuals and thereby improve safety. Despite the benefits of using voltage indicators, what is needed are new and improved voltage indicators and associated circuitry.

### SUMMARY

Therefore, it is a primary object, feature, or advantage of the present invention to improve over the state of the art.

It is a further object, feature, or advantage of the present invention to provide a voltage indicator which may have a small form factor.

It is a still further object, feature, or advantage of the present invention to provide a voltage indicator with stable performance even when used at altitude or in low temperature environments.

Another object, feature, or advantage is to provide a voltage indicator which can accommodate a wide range of voltages.

Yet another object, feature, or advantage is to provide a voltage indicator device or circuit which can be incorporated into a voltage test point.

A still further object, feature, or advantage is to provide a circuit for a voltage indicator which may be adapted for monitoring a single phase or multiple phases.

A further object, feature, or advantage is to provide a circuit which may be used for monitoring AC voltages or DC voltages.

A still further object, feature, or advantage is to provide for a circuit which allows visual indicators to be provided remote from a circuit of a voltage indicator so that the circuit for the voltage indicator device may be mounted within an enclosure and the visual indicators may be viewable from outside of the enclosure.

Another object, feature, or advantage is to provide a voltage indicator which does not require an independent power source such as a battery.

One or more of these and/or other objects, features, or advantages of the present invention will become apparent from the specification and claims that follow. No single embodiment need provide each and every object, feature, or advantage. Different embodiments may have different objects, features, or advantages. Therefore, the present invention is not to be limited to or by any objects, features, or advantages stated herein.

According to one aspect, an electrical safety monitoring device includes a first set of digital switches for each of a plurality of line inputs wherein each of the first set of digital switches is configured to switch between a first state when there is a positive voltage present on a corresponding one of the plurality of line inputs and a second state when there is no voltage present on the corresponding one of the plurality of line inputs. There is also a second set of digital switches for each of the plurality of line inputs wherein each of the second set of digital switches is configured to switch between a first state when there is a negative voltage present on a corresponding one of the plurality of line inputs and a second state when there is no voltage present on the corresponding one of the plurality of line inputs. The electrical safety monitoring device further includes a first set of visual indicators, wherein each of the first set of visual indicators is electrically connected to one of the first set of digital switches and a second set of visual indicators, wherein each of the second set of visual indicators is electrically connected to one of the second set of digital switches. There is a first voltage-controlled oscillator operatively connected to the first set of digital switches for controlling a flash rate of the first set of visual indicators when the positive voltage is present above a first threshold level and a second voltage-controlled oscillator operatively connected to the second set of digital switches for controlling a flash rate of the second plurality of visual indicators when a magnitude of the negative voltage is present above a second threshold level. The threshold levels may both be below 20 volts.

The plurality of line inputs may be a single phase with a first line input and a ground input. The plurality of inputs may include a L1 input, a L2 input, a L3 input, and a ground input and the electrical safety monitoring device may provide for three-phase voltage monitoring. The plurality of line inputs may include a L1 input, a L2 input, a L3 input, a ground input, and a neutral input.

The first voltage-controlled oscillator may be configured such that a higher magnitude of positive voltage present on one of the plurality of line inputs results in a higher flash rate for the one of the plurality of line inputs with the positive voltage present. The second voltage-controlled oscillator may be configured such that a higher magnitude of negative voltage present on one of the plurality line inputs results in a higher flash rate for the one of the plurality of line inputs with the negative voltage present.

Each of the visual indicators may be a light emitting diode. The device may further include a power supply circuit and a power storage circuit operatively connected to the power supply circuit. The device may further include a test point for each of the line inputs.

The device may further include a body and the first set of digital switches, the second set of digital switches, the first voltage-controlled oscillator, and the second voltage-controlled oscillator may be disposed within the body and the first set of visual indicators and the second set of visual indicators may be mounted at a face of the electrical safety monitoring device. Each of the first set of visual indicators and the second set of visual indicators may be labeled on the face. The device may further include a test point for each of the line inputs, the test point for each of the line inputs accessible on the face. The face may be circular and may be partitioned into equal regions for each of the line inputs.

According to another aspect, light tubes such as fiber optics may be used to convey light from one or more LEDs or other visual indicators to a remote location such as to a remotely mounted head unit.

According to another aspect, an electrical safety monitoring device is provided which may include a first set of digital switches for each of a plurality of line inputs wherein each of the first set of digital switches is configured to switch between an on state and an off state based on magnitude of positive voltage on a corresponding one of the plurality of line inputs and a second set of digital switches for each of the plurality of line inputs wherein each of the second set of digital switches is configured to switch between an on state and an off state based on magnitude of negative voltage on a corresponding one of the plurality of line inputs. It may further include a first set of LEDs, wherein each of the first set of LEDs is electrically connected to one of the first set of digital switches and a second set of LEDs, wherein each of the second set of LEDs is electrically connected to one of the second set of digital switches. The device may further include a first voltage-controlled oscillator operatively connected to the first set of digital switches for controlling a flash rate of the first set of LEDs when the positive voltage is present above a first threshold level and a second voltage-controlled oscillator operatively connected to the second set of digital switches for controlling a flash rate of the second plurality of LEDs when a magnitude of the negative voltage is present above a second threshold level. The device may further include a body wherein the first set of digital switches, the second set of digital switches, the first voltage-controlled oscillator, and the second voltage-controlled oscillator are disposed within the body and wherein the first set of LEDs and the second set of LEDs are mounted at a face of the electrical safety monitoring device. The device may further include a test point for each of the line inputs, the test point for each of the line inputs accessible on the face.

### BRIEF DESCRIPTION OF THE DRAWINGS

Illustrated embodiments of the disclosure are described in detail below with reference to the attached drawing figures, which are incorporated by reference herein.

FIG. 1 is a circuit diagram illustrating one example of a circuit for monitoring voltage in a 3-phase system with line inputs L1, L2, L3, and GND.

FIG. 2 is a block diagram illustrating a circuit for monitoring voltage.

FIG. 3 is an example of a voltage indicator device.

FIG. 4 is an example of a voltage indicator device which includes test points.

FIG. 5 is an example of the voltage indicator device where light tubes are used to convey light to a remote location.

FIG. 6 is another example of the voltage indicator device where fiber optics are used to convey light to a remote location.

### DETAILED DESCRIPTION

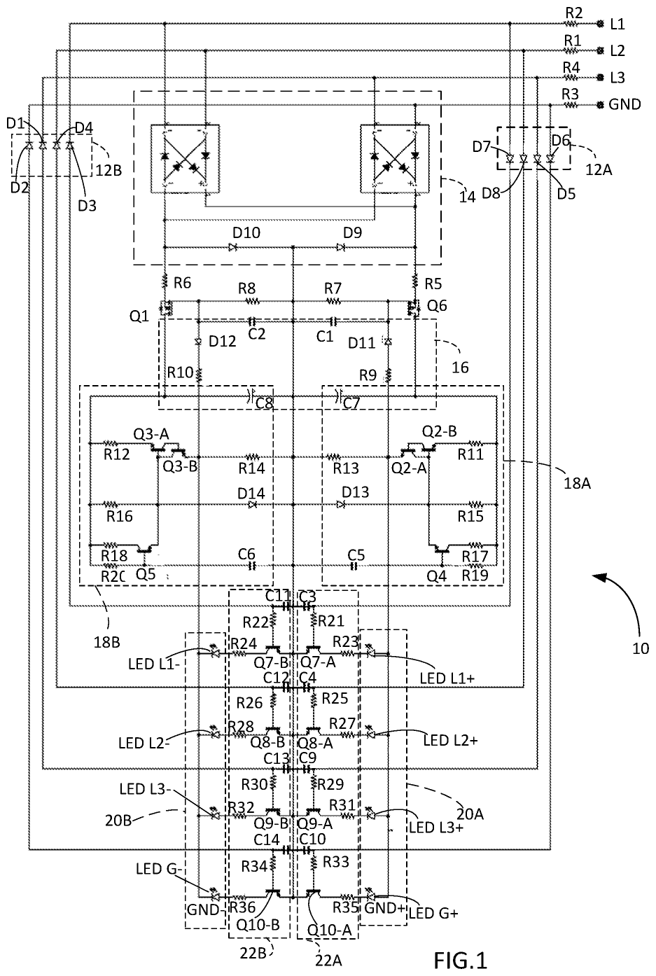

FIG. 1 illustrates one example of a circuit. It is to be understood that the circuit shown is merely representative and that the particular circuit used may vary significantly in terms of the number of phases, the type of visual indicators, the specific components, and the particular specific component values as may be appropriate for a particular application or environment.

In the context of the circuit shown in FIG. 1, the circuit is constructed such that for each line input L1, L2, L3, GND there is a visual indicator to indicate a positive voltage on the line and a visual indicator indicate a negative voltage on the line above a threshold. Each of the visual indicators may flash at a rate associated with the voltage present such that a higher flash rate may generally indicate a higher voltage. Thus, an individual may be alerted as to the presence of voltage as well as an indication of magnitude of the voltage present.

As shown in FIG. 1, there are line inputs associated with a three-phase power connection. These are the L1, L2, L3, and GND line inputs. Each of the line inputs is electrically connected to a resistor R2, R1, R4, R3, respectively and then to a diode D7, D8, D5, D6 within the first set of diodes 12A and a diode D3, D4, D1, D2 within the second set of diodes 12B. The diodes within set 12A are oriented in an opposite direction from the diodes within the set 12B as the first set of diodes 12A are used for a positive voltage portion of the circuit and the second set of diodes 12B are used for a negative voltage portion of the circuit.

A three-phase power supply circuit 14 and power storage circuit 16 are shown. The three-phase power supply circuit 14 may provide for rectifying power from the line inputs L1, L2, L3, GND. Diodes D9, D10 are shown on the output side of the rectifiers. Resistors R5, R6, R7, R8 are shown as well as transistors Q1, Q6. The power storage circuit 16 allows for temporarily storing charge from the three-phase power supply circuit to provide appropriate inputs to the voltage-controlled oscillators 18A, 18B. Capacitors C1, C2, C7, C8 are shown along with diodes D11, D12, and resistors R9, R10. The capacitors provide for storing charge.

As the voltage inputs to the voltage-controlled oscillators 18A, 18B increase in magnitude, the rate of flashing of the corresponding visual indicators also increases, provided that the corresponding digital switches are turned on. When the voltage of one or more of the line inputs is above a threshold voltage then a corresponding digital switch is turned on and the corresponding visual indicator flashes at a frequency set by the corresponding voltage-controlled oscillator.

Note that only two voltage-controlled oscillators 18A, 18B are used in the circuit 10 of FIG. 1. A first voltage-controlled oscillator 18A is used for line inputs when a positive voltage is present in order to show that a positive voltage is present using a corresponding visual indicator. A second voltage-controlled oscillator 18B is used for line inputs when a negative voltage is present in order to show that a negative voltage is present using a corresponding visual indicator. In the first voltage-controlled oscillator, transistors Q2-A, Q2-B, Q4, resistors, R11, R13, R15, R17, R19, diode D13, and capacitor C5 are shown. In the second voltage-controlled oscillator, transistors Q3-A, Q3-B, Q5, resistors R12, R14, R16, R18, R20, diode D14, and capacitor C6 are shown. Although a specific voltage oscillator is shown, it is to be understood that other circuit designs may be used.

There is a first set of digital switches 22A with each digital switch associated within the set of digital switches 22A is used to switch on a corresponding visual indicator within the set 20A these visual indicators are to indicate the presence of a positive voltage. There is a second set of digital switches 22B with digital switch used to switch on a corresponding visual indicator within the set 20B. The circuit for the first set of digital switches includes resistor R21, R23, transistor Q7-A (for the first switch), resistors R25, R27, and transistor Q8-A (for the second switch), resistors R29, R31, transistor Q9-A (for the third switch), resistors R33, R35 and transistor Q10-A (for the fourth switch). For the second set of digital switches, the switches includes resistors R22, R24, transistor Q7-B (for the first switch), resistors R26, R28, transistor Q8-B (for the second switch), resistors R30, R32, transistor Q9-B (for the third switch), resistors R34, R36, transistor Q10-B (for the fourth switch). Bypass Capacitors C11, C3, C12, C4, C13, C9, C14, C10 are also shown. Although transistor switching is shown, other types of digital switching may be performed if desired. For example, a microcontroller may be used to perform digital switching. Thus, the digital switches may form a part of the microcontroller and need not be separate devices. Where a microcontroller is used, the microcontroller may also perform the functionality of the voltage-controlled oscillators.

The visual indicators may be in the form of light emitting diodes and there may be a first set of visual indicators 20A: LED L1+, LED L2+, LED L3+, LED G+ for indicating positive voltages associated with each of the line inputs and a second set of visual indicators 20B: LED L1−, LED L2−, LED L3−, LED G− for indicating negative voltages associated with each of the line inputs.

Although a three-phase power connection is shown as is typically used for AC power lines, the circuit may be modified to accommodate other types of power connectors. For example, instead of a three-phase power connection, a single-phase power connection may be monitored in which case there would need only be two power line inputs. Similarly, a five-wire power connection may be used which include a first line input, a second line input, a third line input, a ground, and a neutral connection. Of course, the circuit may be modified to add additional line inputs by adding the appropriate visual indicators, digital switches, power sense diodes, and/or other circuitry. It is also to be understood that the circuit may also be used for DC voltage lines as well as AC voltage lines and thus the same circuit may be used in a wide range of applications and environments.

The circuitry shown and described may be manufactured and design with solid state circuitry with components with military grade tolerances. This assists in providing various advantages including the ability to use a small form factor and to assist in maintaining stability of the device including at altitude or in low temperature environments. The circuit shown may also be advantageous over some prior art devices in that it accommodates a wide range of voltages. For example, the component values may be selected to allow for an absolute value of under 20 volts to activate an LED and to stay activated up to an absolute value of over 3000 volts. It is to be understood different lower thresholds may be used depending upon the particular application and different higher thresholds may be used depending upon the particular application. It is also to be understood that the voltage-controlled oscillator may be configured such that once a threshold voltage is met, the flash rate either maintains at a constant frequency or else the visual indicator is maintained in an on-state. Thus, at a certain voltage level a corresponding visual indicator or LED may stay on continuously while at a lower absolute voltage level the corresponding visual indicator or LED may flash. In other words, if the voltage on a line input is above a particular threshold the visual indicator or LED may be continuously lit without flashing. If the voltage on the line input is present but drops below the particular threshold then the visual indicator or LED will flash.

Thus, different effects may be obtained depending on the threshold. In one example a relatively low threshold may be set and when the voltage present is above the low threshold, the corresponding visual indicator may be continuously lit or on. If below the threshold, the corresponding visual indicator may flash. Thus, an operator would know that a lower voltage is present if the visual indicator is flashing. The flash rate provides a further indicator of the voltage present with a higher flash rate indicative of a higher voltage but still below the threshold voltage.

In another example, a higher threshold may be set so that over a relatively wide range of voltages, if a voltage is present but less than the higher threshold, the corresponding visual indicator flashes at a flash rate indicative of the voltage present. In this example, the operator may be more concerned about the flash rate, as the higher threshold may be set at a level that is not frequently met. Of course, if the visual indicator is continuously on, that higher threshold has been met.

The line inputs may carry DC voltage instead of AC voltages. Where a positive DC voltage is present on a line input, the corresponding LED will be flash or be lit. Similarly, where a negative DC voltage is present on a line input, the corresponding LED will flash or be lit.

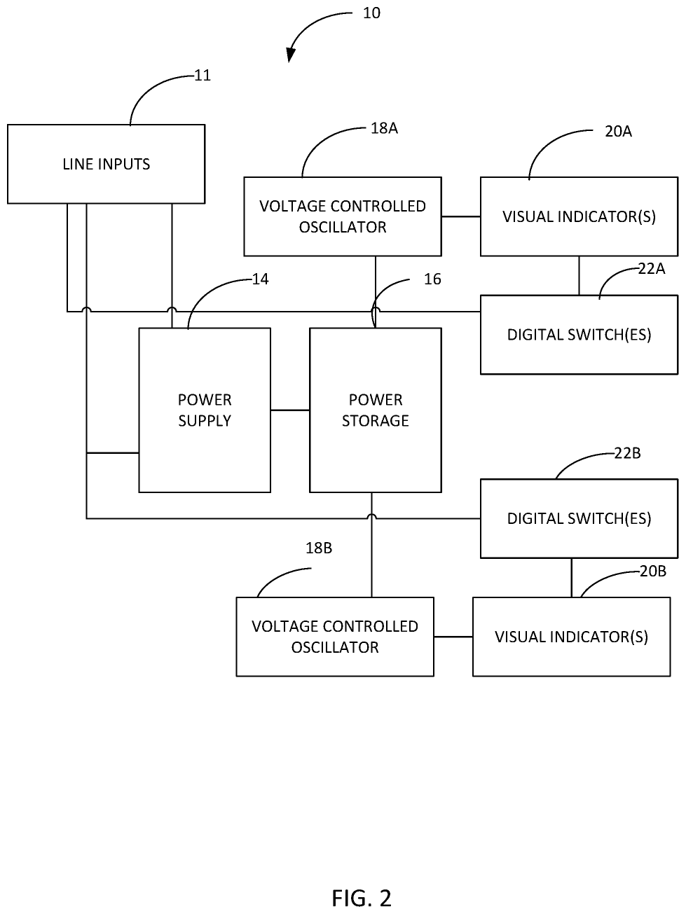

FIG. 2 shows a more generalized diagram which can apply to the circuit shown in FIG. 1 as well as other examples regardless of the number of phases being present or the specific circuits used. As shown in the circuit 10, line inputs 11 are shown which in the three-phase example would include L1, L2, L3, and GND, but may include more or fewer line inputs depending upon the particular situation. Each of the line inputs 11, are electrically connected to a power supply 14 and power storage circuit 16. The digital switches 22A, 22B are used to switch on the visual indicators 20A, 20B which will then flash according to a flash rate as determined by the voltage-controlled oscillators 18A, 18B.

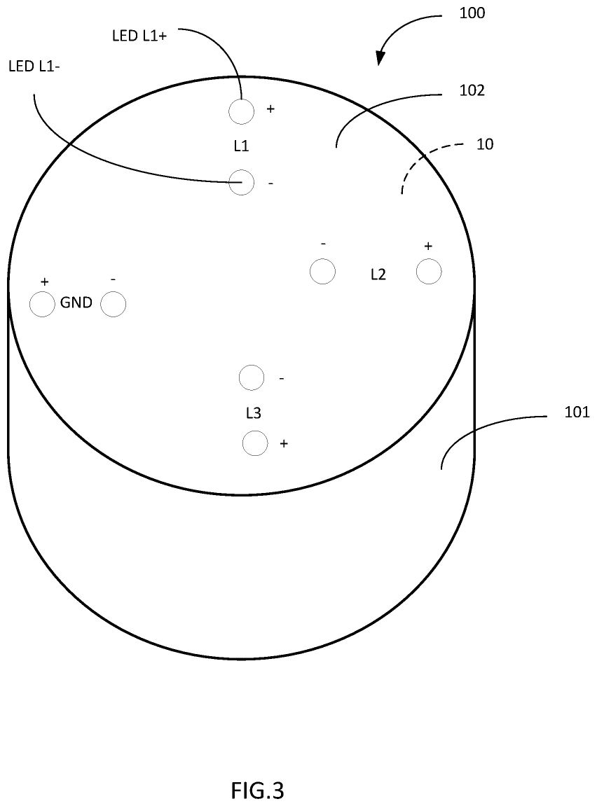

FIG. 3 illustrates one example of a voltage indicator device 100 having a body 101 and a face 102. The face 102 may be circular and divided into multiple regions (here four, one for each line input) such as in the conventional manner. The device may be mounted through the door of an enclosure so that a trained individual may observe the presence of a positive or negative voltage on one or more lines without needing to expose themselves to the voltages. As shown in FIG. 3, there is a label on the face of the device for each line input and each visual indicator (such as an LED) is labeled as “+” or “−”. In operation, when a positive voltage is present on a line input, the corresponding LED will flash at a rate related to the magnitude of the voltage present. Similarly, when a negative voltage is present on a line input, the corresponding LED will flash at a rate related to the magnitude of the voltage present. The device 100 includes the circuit 10 previously shown and described including visual indicators such as in the form of LED L1+, LED L1− for visually indicating the state of line input L1. Although the device shown is circular, it may take on other geometries and the LEDs and labels may be arranged in other manners as may be desirable and/or convenient in a given application or environment.

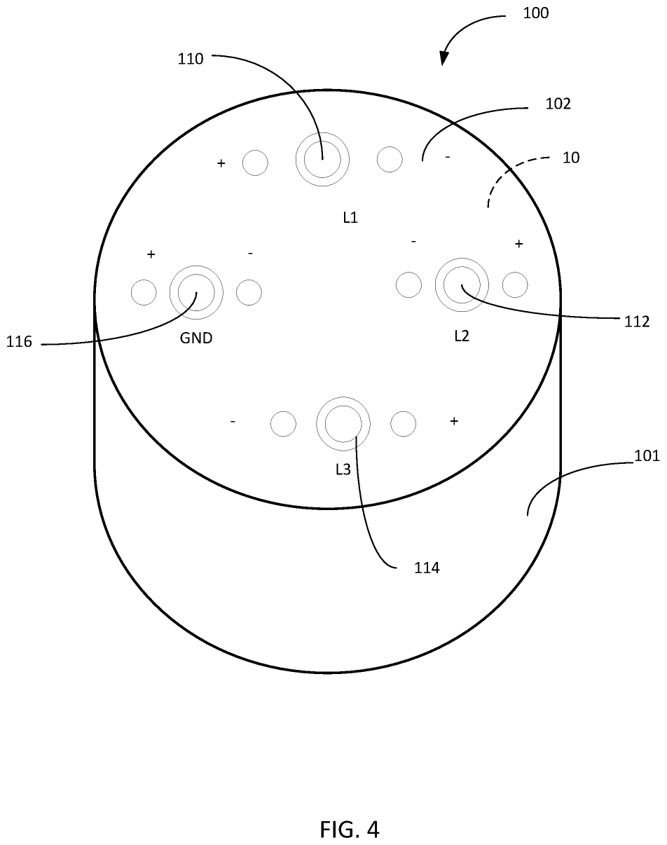

FIG. 4 illustrates another example of a voltage indicator device 100 having a body 101 and a face 102 and including the circuit 10. The device in FIG. 4 differs from that in FIG. 3 in that in addition to have visual indicators in the form of LEDs for each of the line inputs there is also a test point 110, 112, 114, 116 for each of the line inputs. Thus, a voltage indicator device may be incorporated into a test point device, or a test point device may be incorporated into a voltage indicator device, depending upon one's perspective. The test point device may be a Permanent Electrical Safety Device (PESD) that allows a qualified worker to perform an Absence of Voltage Test (AVT) from outside of an electrical cabinet or enclosure. In such an application, test point jacks may be present for each line which is provided in addition to a visual indicator for a positive voltage and a visual indicator for a negative voltage as shown. Although the device shown is circular, it may take on other geometries and the LEDs, test points, and labels may be arranged in other manners as may be desirable and/or convenient in a given application or environment.

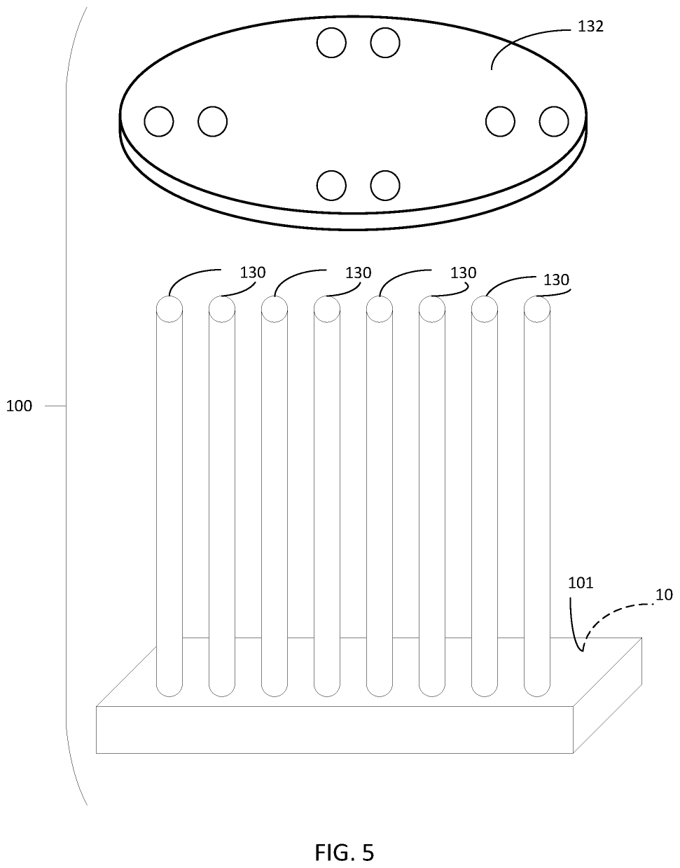

FIG. 5 illustrate another example of a voltage indicator device 100. In the embodiment shown in FIG. 5, the circuit 10 is used but instead of mounting the LEDs (or other visual indicators) on a panel or a door, the body 101 of the device including the circuit 10 may be mounted inside a cabinet such as on a DIN rail or other convenient location. Light tubes 130 such as fibers may carry light produced by the LEDs or other visual indicators of the circuit 10 to a head unit 132 which may mounted on the panel or the door. The light tubes 130 may be longer than what is shown based on the particular distance between the mounting of the body 101 and the head unit 132. It is to be noted that where the light tubes are used, the body 101 is mounted within an enclosure, no voltage would be communicated to the outside of the panel, only light carried by the optical fibers or other light tubes 130. The head unit 132 may have similar size, configuration, or labeling as a face of other embodiments previously shown and described, but may alternatively be otherwise sized or shaped as may be convenient in a particular application or environment. The body 101 may be of any number of styles or configurations as desired. For example, the body 101 may be sized or shaped to better fit to a DIN rail or to otherwise mounting within a cabinet. Although eight light tubes 130 are shown, more or fewer may be present depending upon the number of voltage lines or phases being monitored.

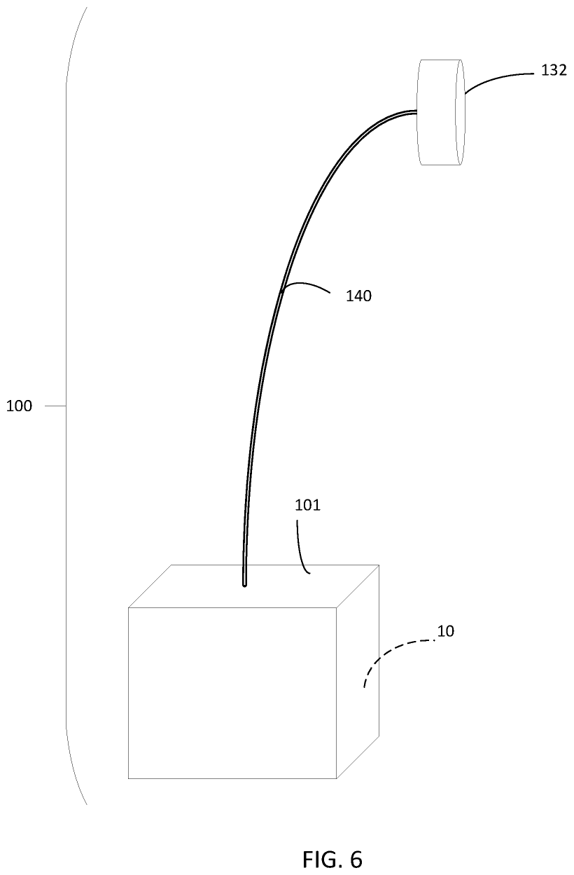

FIG. 6 is another example of the voltage indicator device where fiber optics are used to convey light to a remote location. FIG. 6 is the same system 100 as in FIG. 5 except that the light tubes or optical fibers are bundled together within a cable 140 which provides a sleeve or sheath for the bundle of optical fibers.

The electrical safety monitoring device shown and described herein is well-suited to the industrial environment such as to mount to panels or doors of electrical enclosures or elsewhere. It is to be understood, however, that the electrical safety monitoring device may be used elsewhere such as in homes, on solar panels, or wherever else voltage monitoring is necessary or desired. It is to be understood that the size, configuration, and number of line inputs may vary based on the specific application.

The invention is not to be limited to the particular embodiments described herein. In particular, the invention contemplates numerous variations in the particular components used, component values, voltage ranges, types of visual indicators, threshold values, device shapes and geometries, and other variations, options, and alternatives. The foregoing description has been presented for purposes of illustration and description. It is not intended to be an exhaustive list or limit any of the invention to the precise forms disclosed. It is contemplated that other alternatives or exemplary aspects are considered included in the invention. The description is merely examples of embodiments, processes, or methods of the invention. It is understood that any other modifications, substitutions, and/or additions can be made, which are within the intended spirit and scope of the invention.

What is claimed is:

1. An electrical safety monitoring device, comprising:
a first set of digital switches for each of a plurality of line inputs wherein each of the first set of digital switches is configured to switch between a first state when there is a positive voltage present on a corresponding one of the plurality of line inputs and a second state when there is no voltage present on the corresponding one of the plurality of line inputs;
a second set of digital switches for each of the plurality of line inputs wherein each of the second set of digital switches is configured to switch between a first state when there is a negative voltage present on a corresponding one of the plurality of line inputs and a second state when there is no voltage present on the corresponding one of the plurality of line inputs;
a first set of visual indicators, wherein each of the first set of visual indicators is electrically connected to one of the first set of digital switches;
a second set of visual indicators, wherein each of the second set of visual indicators is electrically connected to one of the second set of digital switches;
a first voltage-controlled oscillator operatively connected to the first set of digital switches for controlling a flash rate of the first set of visual indicators when the positive voltage is present above a first threshold level;
a second voltage-controlled oscillator operatively connected to the second set of digital switches for controlling a flash rate of the second plurality of visual indicators when a magnitude of the negative voltage is present above a second threshold level.

2. The electrical safety monitoring device of claim 1 wherein the plurality of line inputs includes a first line input and a ground input.

3. The electrical safety monitoring device of claim 1 wherein the plurality of line inputs comprises a L1 input, a L2 input, a L3 input, and a GND input and the electrical safety monitoring device provides for three-phase voltage monitoring.

4. The electrical safety monitoring device of claim 1 wherein the plurality of line inputs comprises a L1 input, a L2 input, a L3 input, a GND input, and a neutral input.

5. The electrical safety monitoring device of claim 1 wherein the first voltage-controlled oscillator is configured such that a higher magnitude of positive voltage present on one of the plurality of line inputs results in a higher flash rate for the one of the plurality of line inputs with the positive voltage present.

6. The electrical safety monitoring device of claim 5 wherein the second voltage-controlled oscillator is configured such that a higher magnitude of negative voltage present on one of the plurality line inputs results in a higher flash rate for the one of the plurality of line inputs with the negative voltage present.

7. The electrical safety monitoring device of claim 1 wherein when a magnitude of voltage is sufficiently high, a corresponding one of the visual indicators maintains a continuously on state.

8. The electrical safety monitoring device of claim 1 wherein each of the visual indicators is a light emitting diode (LED).

9. The electrical safety monitoring device of claim 1 further comprising a power supply circuit.

10. The electrical safety monitoring device of claim 9 further comprising a power storage circuit operatively connected to the power supply circuit.

11. The electrical safety monitoring device of claim 1 wherein the first voltage level and the second voltage level are both below 20 volts.

12. The electrical safety monitoring device of claim 1 further comprising a test point for each of the line inputs.

13. The electrical safety monitoring device of claim 1 further comprising a body wherein the first set of digital switches, the second set of digital switches, the first voltage-controlled oscillator, and the second voltage-controlled oscillator are disposed within the body and wherein the first set of visual indicators and the second set of visual indicators are mounted at a face of the electrical safety monitoring device.

14. The electrical safety monitoring device of claim 13 wherein each of the first set of visual indicators and the second set of visual indicators are labeled on the face.

15. The electrical safety monitoring device of claim 13 further comprising a test point for each of the line inputs, the test point for each of the line inputs accessible on the face.

16. The electrical safety monitoring device of claim 13 wherein the face is circular.

17. The electrical safety monitoring device of claim 1 further comprising a light tube for each of the first set of visual indicators and each of the second set of visual indicators to communicate light to a remote position.

18. An electrical safety monitoring device comprising:
a first set of digital switches for each of a plurality of line inputs wherein each of the first set of digital switches is configured to switch between an on state and an off state based on magnitude of positive voltage on a corresponding one of the plurality of line inputs;
a second set of digital switches for each of the plurality of line inputs wherein each of the second set of digital switches is configured to switch between an on state and an off state based on magnitude of negative voltage on a corresponding one of the plurality of line inputs
a first set of LEDs, wherein each of the first set of LEDs is electrically connected to one of the first set of digital switches;
a second set of LEDs, wherein each of the second set of LEDs is electrically connected to one of the second set of digital switches;
a first voltage-controlled oscillator operatively connected to the first set of digital switches for controlling a flash rate of the first set of LEDs when the positive voltage is present above a first threshold level;
a second voltage-controlled oscillator operatively connected to the second set of digital switches for controlling a flash rate of the second plurality of LEDs when a magnitude of the negative voltage is present above a second threshold level.

19. The electrical safety monitoring device of claim 18 further comprising a body wherein the first set of digital switches, the second set of digital switches, the first voltage-controlled oscillator, and the second voltage-controlled oscillator are disposed within the body and wherein the first set of LEDs and the second set of LEDs are mounted at a face of the electrical safety monitoring device.

20. The electrical safety monitoring device of claim 19 further comprising a test point for each of the line inputs, the test point for each of the line inputs accessible on the face.

21. The electrical safety monitoring device of claim 18 wherein when a magnitude of voltage is sufficiently high, a corresponding one of the visual indicators maintains a continuously on state.

22. The electrical safety monitoring device of claim 18 further comprising a light tube for each of the first set of LEDs and the second set of LEDs to convey light to a remote location.
